(19) United States
(12) Patent Application Publication
(10) Pub. No.: US 2015/0318288 A1
(43) Pub. Date: Nov. 5, 2015

(54) VERTICAL TRANSISTOR STATIC RANDOM ACCESS MEMORY CELL

(71) Applicant: GLOBALFOUNDRIES Inc., Grand Cayman (KY)

(72) Inventors: Kwan-Yong Lim, Niskayuna, NY (US); Ryan Ryoung-Han Kim, Albany, NY (US)

(73) Assignee: GLOBALFOUNDRIES Inc., Grand Cayman (KY)

(21) Appl. No.: 14/267,405

(22) Filed: May 1, 2014

(51) Int. Cl. H01L 27/11; H01L 29/78; H01L 29/66

(52) U.S. Cl. CPC H01L 27/1104; H01L 29/66666; H01L 29/7827

(57) ABSTRACT

Various methods of forming a vertical static random access memory cell and the resulting devices are disclosed. One method includes forming a plurality of pillars of semiconductor material on a substrate, forming first source/drain regions on a lower portion of each of the pillars, forming a gate electrode around each of the pillars above the first source/drain region, forming a second source/drain region on a top portion of each of the pillars above the gate electrode, wherein the first and second source/drain regions and the gate electrode on each pillar defines a vertical transistor, and interconnecting the vertical transistors to define a static random access memory cell.

### BACKGROUND OF THE INVENTION

1. Field of the Invention

The present disclosure generally relates to the fabrication of semiconductor devices, and, more particularly, to a vertical static random access memory cell and various methods of forming same.

2. Description of the Related Art

Semiconductor memory devices are in widespread use in many modern integrated circuit devices and in many consumer products. In general, memory devices are the means by which electrical information is stored. There are many types of memory devices, SRAMs (Static Random Access Memory), DRAMs (Dynamic Random Access Memory), ROMs (Read Only Memory), etc., each of which has its own advantages and disadvantages relative to other types of memory devices. For example, SRAMs are typically employed in applications where higher speed and/or reduced power consumption is important, e.g., cache memory of a microprocessor, mobile phones and other mobile consumer products, etc. Millions of such memory devices are typically included in even very basic electronic consumer products. Irrespective of the type of memory device, there is a constant drive in the industry to increase the performance and durability of such memory devices. In typical operations, an electrical charge (HIGH) is stored in the memory device to represent a digital “1”, while the absence of such an electrical charge or a relatively low charge (LOW) stored in the device indicates a digital “0”. Read/write circuitry is used to access the memory device to store digital information on such a memory device and to determine whether or not a charge is presently stored in the memory device. These read/write cycles typically occur millions of times for a single memory device over its effective lifetime.

In general, efforts have been made to reduce the physical size of such memory devices, particularly reducing the physical size of components of the memory devices, such as transistors, to increase the density of memory devices, thereby increasing performance and decreasing the costs of the integrated circuits incorporating such memory devices. Increases in the density of the memory devices may be accomplished by forming smaller structures within the memory device and by reducing the separation between the memory devices and/or between the structures that make up the memory device. Often, these smaller design rules are accompanied by layout, design and architectural modifications which are either made possible by the reduced sizes of the memory device or its components, or such modifications are necessary to maintain performance when such smaller design rules are implemented. As an example, the reduced operating voltages used in many modern-day conventional integrated circuits are made possible by improvements in design, such as reduced gate insulation thicknesses in the component transistors and improved tolerance controls in lithographic processing. On the other hand, reduced design rules make reduced operating voltages essential to limit the effects of hot carriers generated in small size devices operating at higher, previously conventional operating voltages.

Making SRAMs in accordance with smaller design rules, as well as using reduced internal operating voltages, can reduce the stability of SRAM cells. Reduced operating voltages and other design changes can reduce the voltage margins which ensure that an SRAM cell remains in a stable data state during a data read operation, increasing the likelihood that the read operation could render indeterminate or lose entirely the data stored in the SRAM cell. As shown in FIG. 1, a typical 6T (six transistor) SRAM memory cell 100 includes two NMOS pass gate transistors PG1, PG2, two PMOS pull-up transistors PU1, PU2, and two NMOS pull-down transistors PD1, PD2. Each of the PMOS pull-up transistors PU1, PU2 has its gate connected to the gate of a corresponding NMOS pull-down transistor PD1, PD2. The PMOS pull-up transistors PU1, PU2 have their drain regions connected to the drain regions of corresponding NMOS pull-down transistors PD1, PD2 to form inverters having a conventional configuration. The source regions of the PMOS pull-up transistors PU1, PU2 are connected to a high reference potential, typically VDD, and the source regions of the NMOS pull-down transistors PD1, PD2 are connected to a lower reference potential, typically VSS or ground. The gates of the PMOS pull-up transistor PUI1 and the NMOS pull-down transistor PD1, which make up one inverter, are connected to the drain regions of the transistors PU2, PD2 of the other inverter. Similarly, the gates of the PMOS pull-up transistor PU2 and the NMOS pull-down transistor PD2, which make up the other inverter, are connected to the drain regions of the transistors PU1, PD1. Hence, the potential present on the drain regions of the transistors PU1, PD1 (node N1) of the first inverter is applied to the gates of transistors PU2, PD2 of the second inverter and the charge serves to keep the second inverter in an ON or OFF state. The logically opposite potential is present on the drain regions of the transistors PU2, PD2 (node N2) of the second inverter and on the gates of the transistors PU1, PD1 of the first inverter, keeping the first inverter in the complementary OFF or ON state relative to the second inverter. Thus, the latch of the illustrated SRAM cell 100 has two stable states: a first state with a predefined potential present on charge storage node N1 and a low potential on charge storage node N2; and a second state with a low potential on charge storage node N1 and the predefined potential on charge storage node N2. Binary data are recorded by toggling between the two states of the latch. Sufficient charge must be stored on the charge storage node, and thus on the coupled gates of associated inverter, to unambiguously hold one of the inverters “ON” and unambiguously hold the other of the inverters “OFF”, thereby preserving the memory state. The stability of an SRAM cell 100 can be quantified by the margin by which the potential on the charge storage nodes can vary from its nominal value while still keeping the SRAM 100 cell in its original state.

Data is read out of the conventional SRAM cell 100 in a non-destructive manner by selectively coupling each charge storage node (N1, N2) to a corresponding one of a pair of complementary bit lines (BL, BLB). The selective coupling is accomplished by the aforementioned of pass gate transistors PG1, PG2, where each pass gate transistor is connected between one of the charge storage nodes (N1, N2) and one of the complementary bit lines (BL, BLB). Word line signals are provided to the gates of the pass gate transistors PG1, PG2 to switch the pass gate transistors ON during data read operations. Charge flows through the ON pass gate transistors to or from the charge storage nodes (N1, N2), discharging one of the bit lines and charging the other of the bit lines. The voltage changes on the bit lines are sensed by a differential amplifier (not shown).

Prior to a read operation, the bit lines BL, BLB are typically equalized at a voltage midway between the high and low reference voltages, typically ½(VDD−VSS), and then a signal on the word line WL turns the pass gate transistors PG1, PG2 ON. As an example, consider that N1 is charged to a predetermined potential of VDD and N2 is charged to a lower potential VSS. When the pass gate transistors PG1, PG2 turn ON, charge begins flowing from node N1 through pass gate transistor PG1 to bit line BL. The charge on node N1 begins to drain off to the bit line BL and is replenished by charge flowing through pull-up transistor PU1 to node N1. At the same time, charge flows from bit line BLB through pass gate transistor PG2 to node N2 and the charge flows from the node N2 through the pull-down transistor PD2. To the extent that more current flows through pass gate transistor PG1 than flows through pull-up transistor PU1, charge begins to drain from the node N1, which, on diminishing to a certain level, can begin turning OFF pull-down transistor PD2. To the extent that more current flows through pass transistor PG2 than flows through pull-down transistor PD2, charge begins to accumulate on charge storage node N2, which, on charging to a certain level, can begin turning OFF pull-up transistor PU1.

For the SRAM cell's latch to remain stable during such a data reading operation, at least one of the charge storage nodes (N1, N2) within the SRAM cell 100 must charge or discharge at a faster rate than charge flows from or to the corresponding bit line. In the past, one technique used to achieve this control is to configure the various transistors of the SRAM cell 100 such that the pass gate transistors PG1, PG2 are strong enough to over-write the pull-up transistors PU1, PU2 during a write operation, but weak enough so as to not over-write the pull-down transistors PD1, PD2 during a read operation.

For highly scaled memory cells, this difference in the gate widths of the various transistors may not provide enough confidence that the SRAM cell 100 will remain stable during operation. Another technique that has been employed, in addition to the difference in gate widths, is to provide an additional well implant (P-type dopant) for the pass gate transistors PG1, PG2 in an attempt to further insure that the threshold voltage (Vt) of the pass gate transistors PG1, PG2 is sufficiently high so as not to flip the bit cell during a read operation. This technique is referred to as providing a voltage threshold mismatch (Vtmm).

As SRAM devices continue to scale down, such as below 10 nm, the transistors are susceptible to short channel effects due to the corresponding scaling of the gate electrodes. These effects degrade Vtmm as well as memory cell stability.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a vertical static random access memory cell and the resulting device. One illustrative method disclosed herein includes forming a plurality of pillars of semiconductor material on a substrate, forming first source/drain regions on a lower portion of each of the pillars, forming a gate electrode around each of the pillars above the first source/drain region, forming a second source/drain region on a top portion of each of the pillars above the gate electrode, wherein the first and second source/drain regions and the gate electrode on each pillar defines a vertical transistor, and interconnecting the vertical transistors to define a static random access memory cell.

One illustrative device disclosed herein includes, among other things a memory cell, including a plurality of vertical transistors, each including a pillar of semiconductor material, a first source/drain region on a lower portion of the pillar, a gate electrode disposed around the pillar above the first source/drain region, a second source/drain region on a top portion of the pillar above the gate electrode and interconnections between the vertical transistors to define a static random access memory cell.

Another illustrative device disclosed herein includes, among other things a memory array, including a plurality of devices arranged in columns and rows, each device including a plurality of vertical transistors, each including a pillar of semiconductor material, a first source/drain region on a lower portion of the pillar, a gate electrode disposed around the pillar above the first source/drain region, a second source/drain region on a top portion of the pillar above the gate electrode and interconnections between the vertical transistors to define a static random access memory cell including first and second pass gate transistors, first and second pull-down transistors, and first and second pull-up transistors. The memory array further includes a plurality of bit line pairs, each pair coupled to the second source/drain regions of respective first and second pass gates of a column of devices and a plurality of word lines, each coupled to the gate electrodes of the first and second pass gates of a row of static random access memory cells.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically depicts an illustrative prior art SRAM memory device;

FIGS. 2A-2R depict various methods disclosed herein of forming a vertical SRAM cell;

FIG. 3 is a top view of a vertical SRAM cell illustrating contacts for interfacing with the cell;

FIG. 4 is a diagram illustrating a vertical SRAM memory array and interconnect wiring structure;

FIG. 5 is a diagram of an alternative embodiment of a vertical SRAM cell; and

FIG. 6 is a diagram of an alternative embodiment of a vertical SRAM cell with differing relative channel widths for the transistors in the cell.

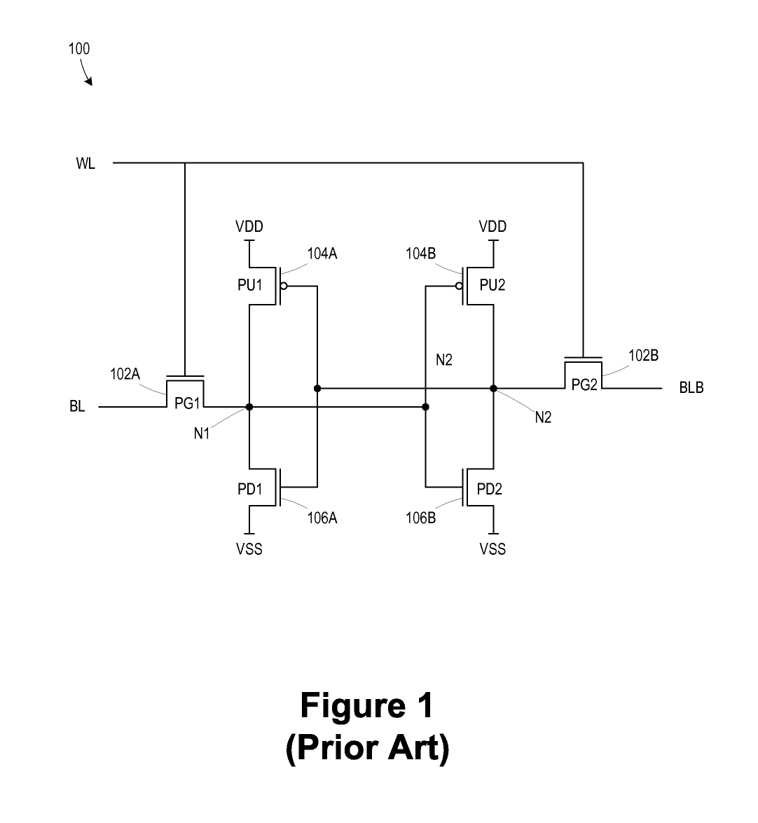

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming reduced resistance local interconnect structures and the resulting semiconductor devices. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

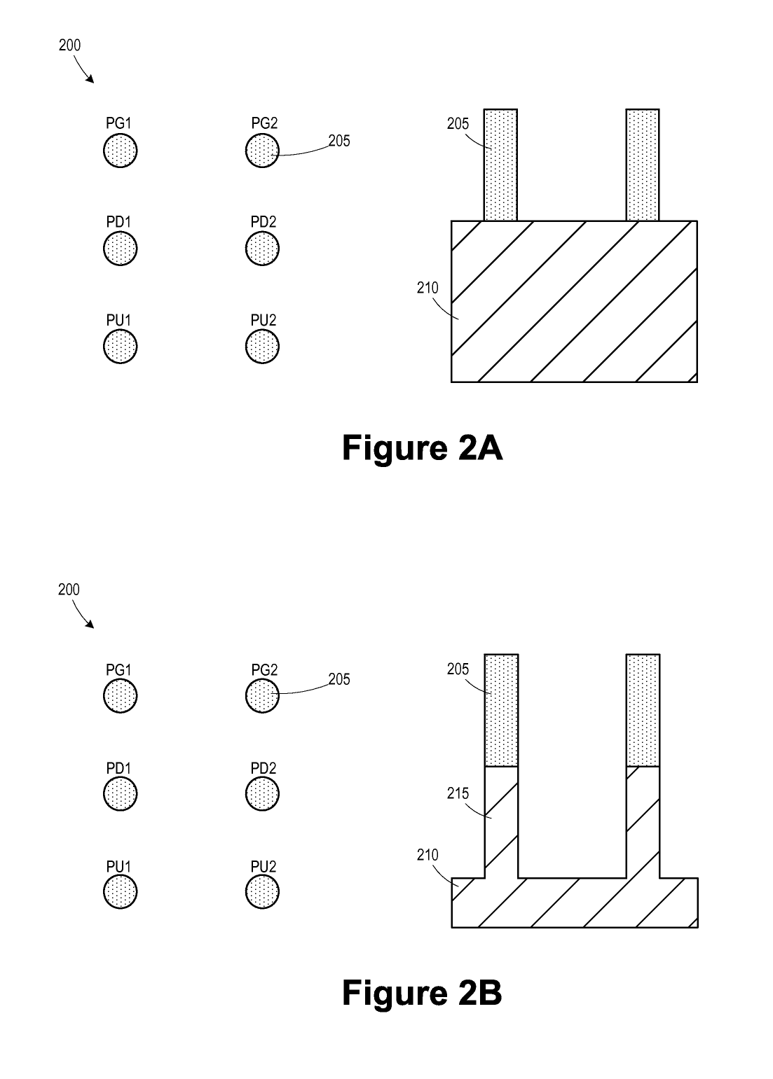

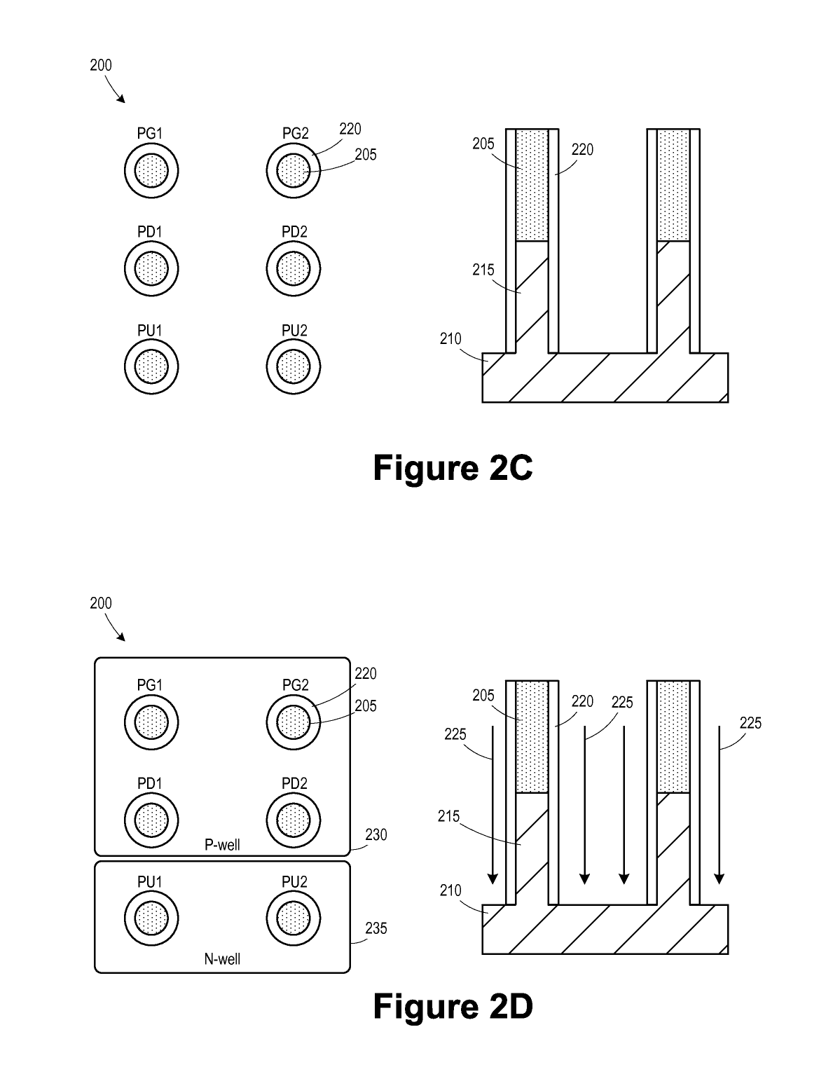

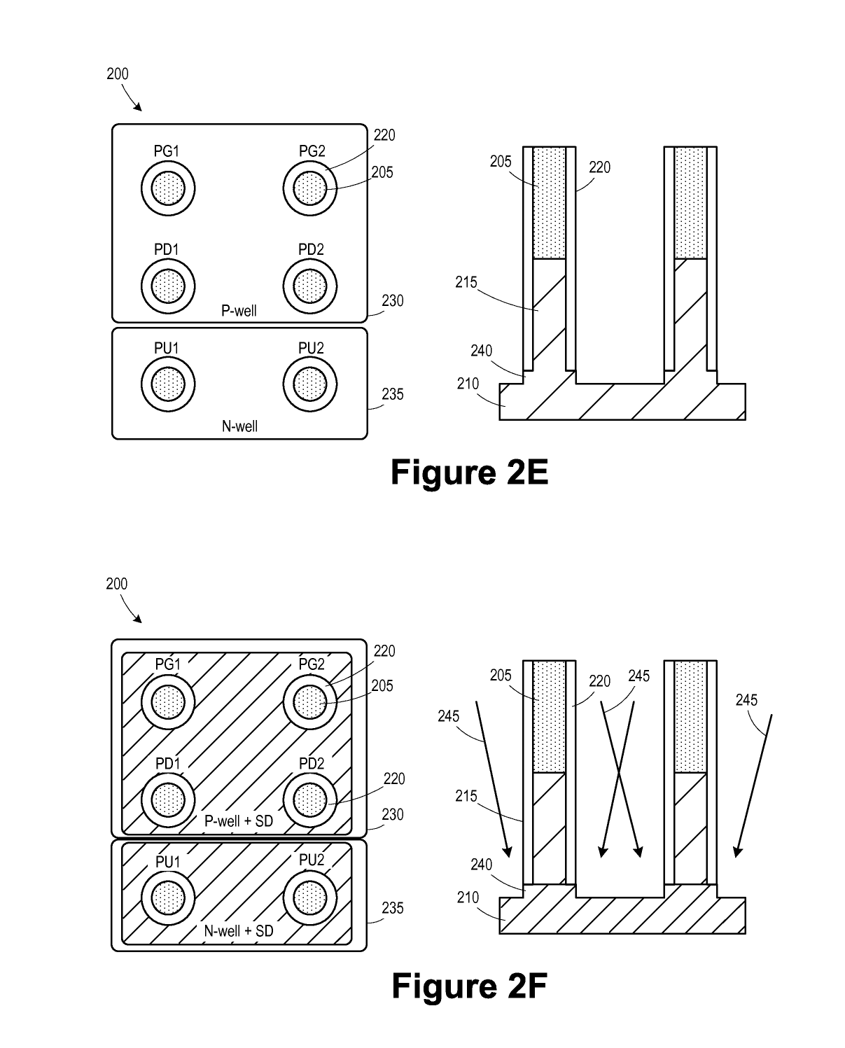

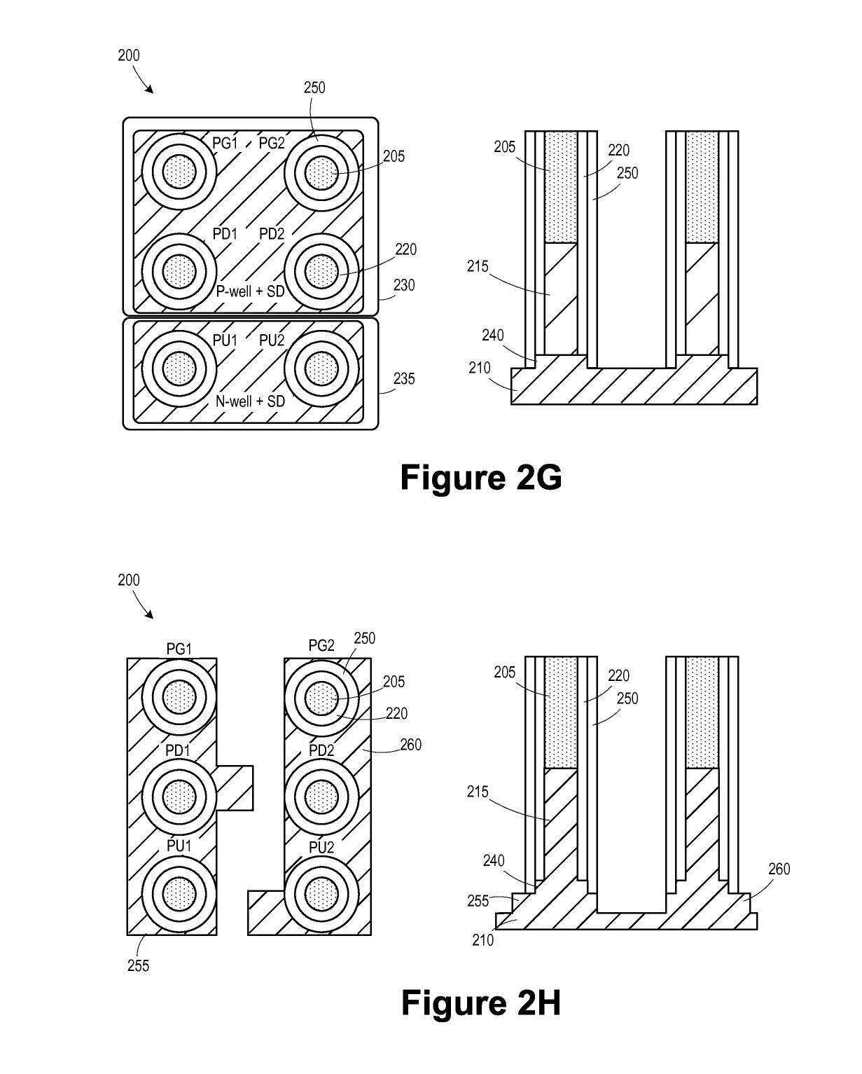

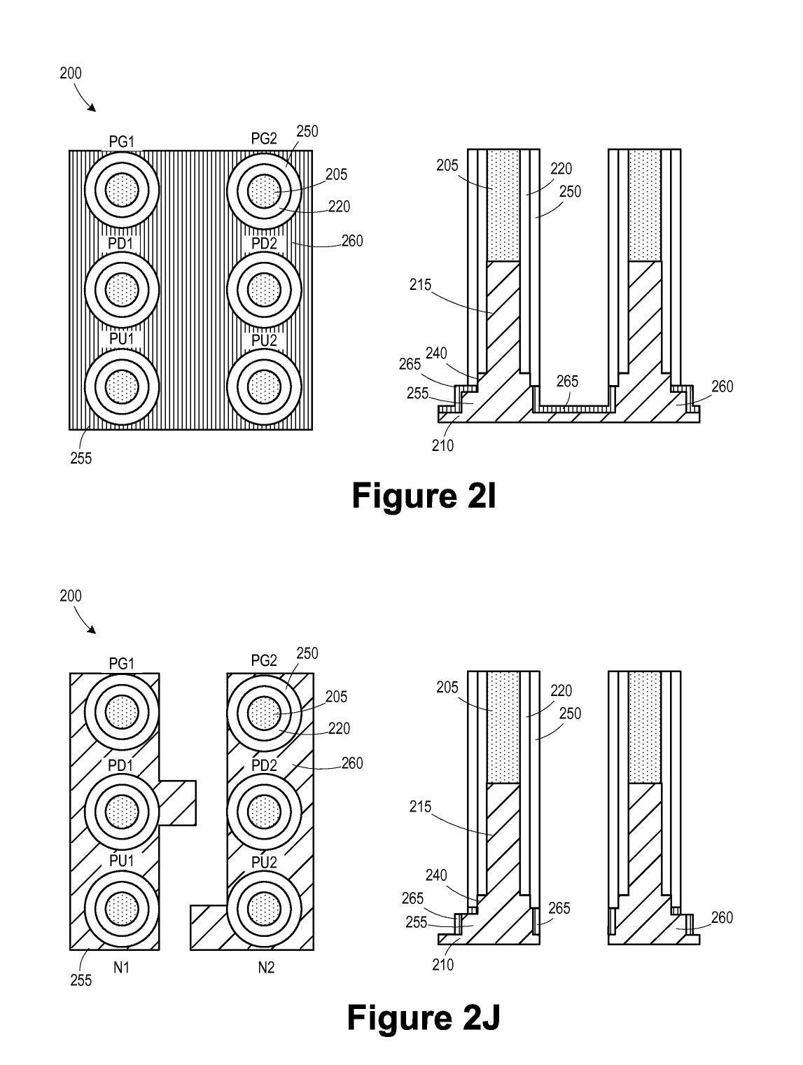

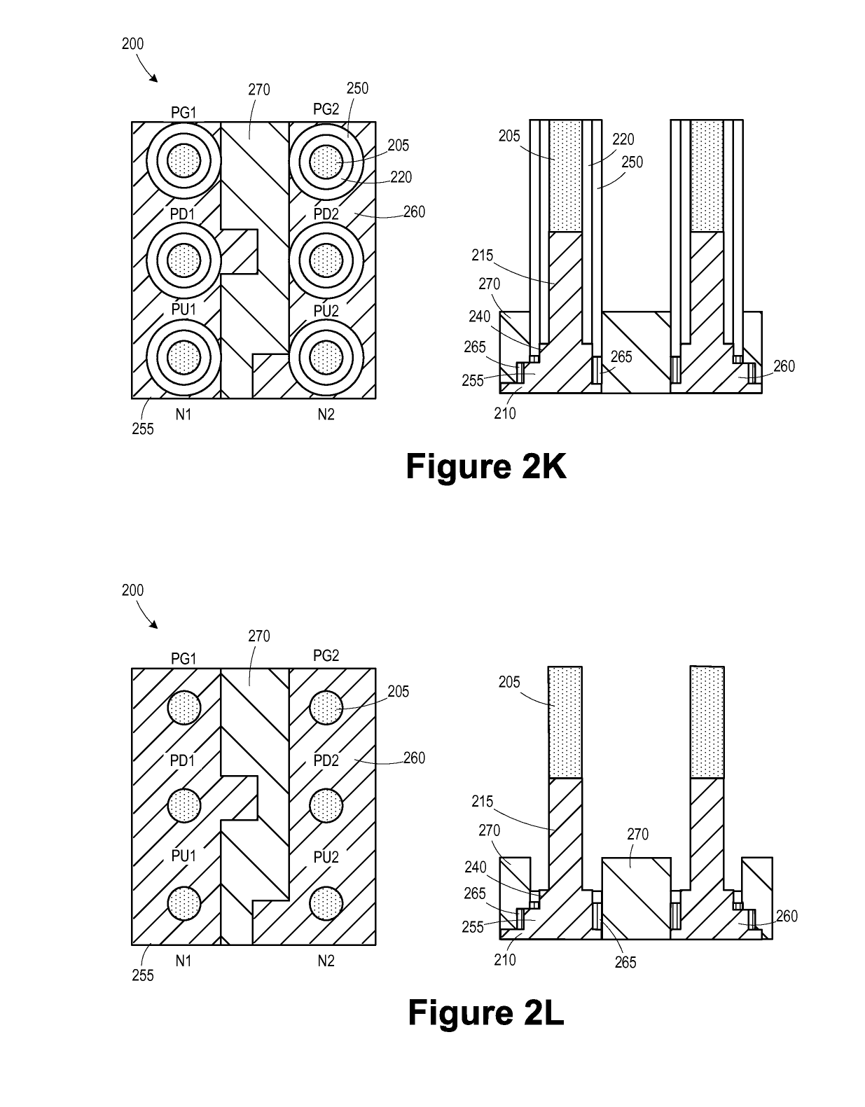

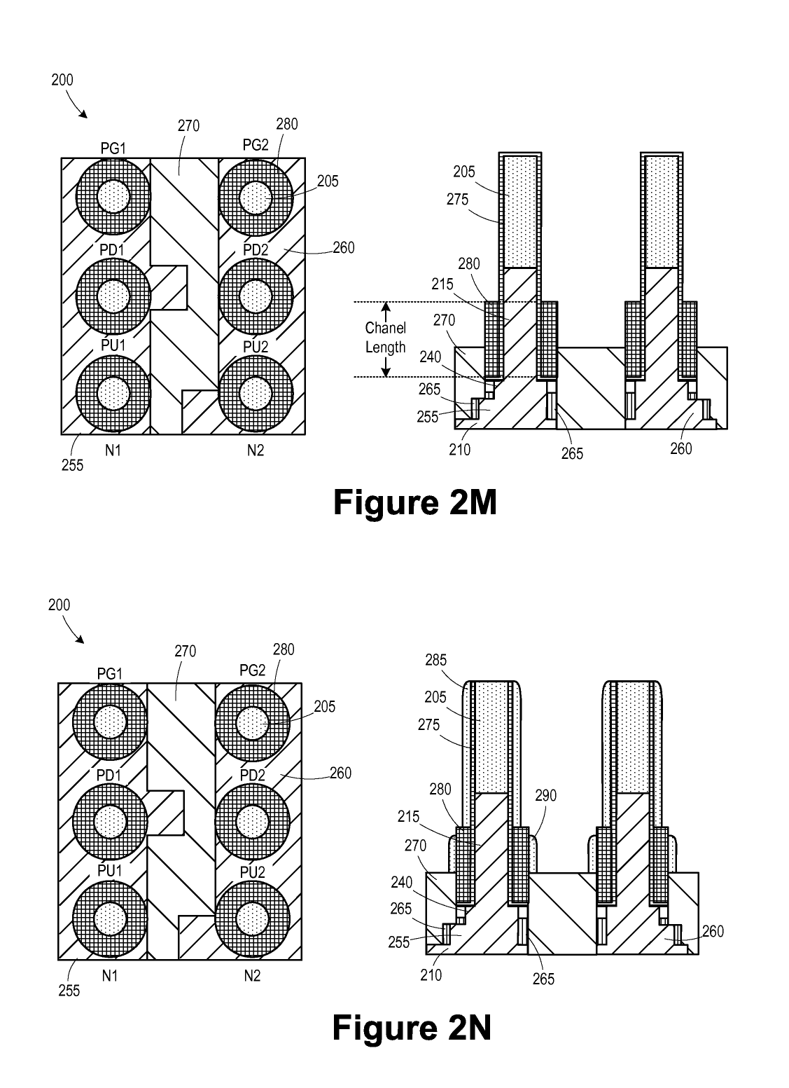

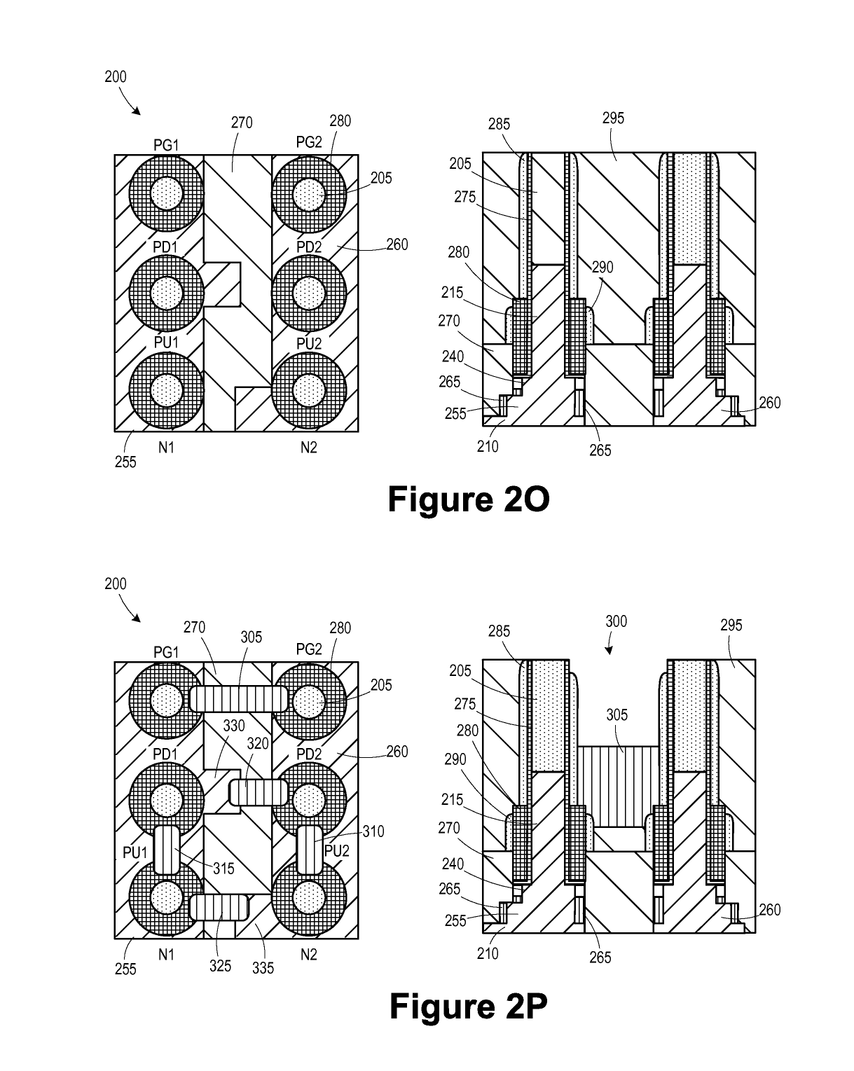

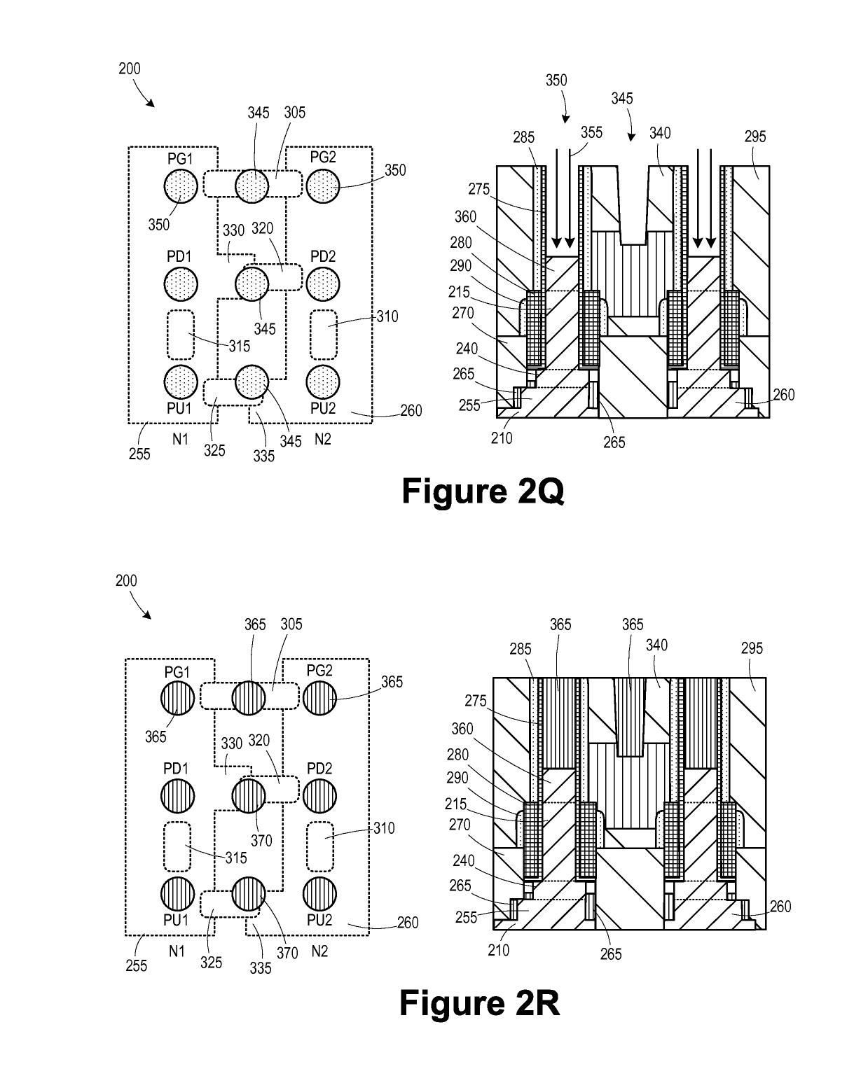

FIGS. 2A-2R illustrate various methods for forming a vertical six transistor (6T) static random access memory (SRAM) cell 200, including pass gate transistors PG1, PG2, pull-down transistors PD1, PD2, and pull-up transistors PU1, PU2. The particular arrangement of the transistors may vary. FIGS. 2A-2R show a top view and a cross-sectional view of the memory cell 200 in the process of being fabricated. FIG. 2A depicts the (SRAM) cell 200 with a hard mask layer 205 (e.g., SiO₂) formed and patterned above a silicon substrate 210. For ease of illustration, the horizontal surface of the substrate 210 is not shown in the top view. The hard mask layer 205 may be formed by depositing a layer of hard mask material, forming a photoresist layer above the hard mask material, patterning the photoresist layer and etching the hard mask material in the presence of the photoresist material, as is known to those of ordinary skill in the art.

FIG. 2B depicts the (SRAM) cell 200 after an etch process, such as an anisotropic etch process, removes material from the silicon substrate 210 to define silicon pillars 215. FIG. 2C depicts the (SRAM) cell 200 with sidewall spacers 220 (e.g., silicon nitride) formed on sidewalls of the hard mask layer 205 and the pillars 215. The sidewall spacers 220 may be formed by forming a conformal layer of spacer material over the substrate 210 and anisotropically etching the spacer material until the portions formed over horizontal portions of the substrate 210 and hard mask layer 205 are removed. Although the pillars 215 are illustrated as having circular cross-sections, other cross-sectional shapes, such as ovals, squares, rectangles, etc., may be employed.

FIG. 2D depicts the (SRAM) cell 200 after well implantation processes 225 are performed to form a P-well 230 in regions near the PG1, PG2, PD1 and PD2 transistors, and an N-well 235 in regions near the PU1 and PU2 transistors. Separate implantation steps with different dopant types may be performed in the presence of implantation masks (not shown) to define the P-well 230 (e.g., B, BF₂) and the N-well 235 (e.g., As, P).

FIG. 2E depicts the (SRAM) cell 200 after an etching step is performed to extend the pillars 215 to define lower source/drain (SD) regions 240. FIG. 2F depicts the (SRAM) cell 200 after source/drain (SD) implantation processes 245 are performed to form lightly doped drain (LDD) and dope the SD regions 240, using an N-type dopant (e.g., As, P) for the PG1, PG2, PD1, and PD2 transistors and using a P-type dopant (e.g., B, BF₂, Sb) for the PU1 and PU2 transistors. Separate implantation steps with different dopant types may be performed in the presence of implantation masks (not shown).

FIG. 2G illustrates the SRAM cell 200 after the formation of a second sidewall spacer 250 (e.g., SiN, SiBN, SiBCN, SiCN, SiOCN) to cover the SD regions 240. FIG. 2H depicts the (SRAM) cell 200 after a patterning process is performed to define active regions 255, 260 (e.g., islands of substrate material) below the SD regions 240 to connect the SD regions 240 of the PG1, PD1 and PU1 transistors and the SD regions (not shown) of the PG2, PD2 and PU2 transistors, respectively. An implantation mask (not shown) is employed to define the shapes of the active regions 255, 260. The active regions 255, 260 are already doped from the LDD and SD implantation processes 245 shown in FIG. 2F. For ease of illustration, the horizontal surface of the substrate 210 and the wells 230, 235 are not shown in the plan view in FIG. 2H.

FIG. 2I depicts the (SRAM) cell 200 after a silicide layer 265 is formed on the active regions 255, 260 by forming a metal layer (e.g., Ti, Ni, Co, Pt or a combination thereof) above the substrate 210, reacting the metal to form the silicide layer 265, and removing unreacted portions of the metal. FIG. 2J depicts the (SRAM) cell 200 after the silicide layer is removed from the horizontal surface of the active regions 255, 260 by performing an anisotropic etch process. Portions of the silicide layer 265 remain on sidewalls of the active regions 255, 260. The remaining portions of the silicide layer 265 form a conductive path across the active regions 255, 260, thereby electrically connecting the SD regions 240 of the PG1, PD1 and PU1 transistors and the SD regions (not shown) of the PG2, PD2 and PU2 transistors to define the nodes N1 and N2, respectively.

FIG. 2K depicts the (SRAM) cell 200 after a dielectric layer 270 (e.g., SiO₂) is formed between the active regions 255, 260. The dielectric layer 270 may be formed by blanket deposition, followed by a planarization process, and wet or dry etch-back process. FIG. 2L depicts the (SRAM) cell 200 after the sidewall spacers 220, 250 are removed.

FIG. 2M depicts the (SRAM) cell 200 after a gate insulation layer 275 (e.g., SiO₂, HfO₂, Hf—Si—O, ZrO₂) and a gate electrode material 280 (e.g., doped polysilicon, doped polysilicon germanium, WN, TiN, TaN) are formed. The gate electrode material 280 may be formed be depositing the conductive material and performing a patterned etch-back process. Since the transistors PG1, PG2, PU1, PU2, PD1, PD2 are vertical, the channel length is determined by the height of the gate electrode material 280. Increasing the channel length increases the height of the transistors, but does not decrease their density. In this manner, the performance characteristics of the transistors can be managed separately from density constraints. The channel width of the transistors is determined by the cross-sectional areas of the pillars 215.

FIG. 2N depicts the (SRAM) cell 200 after spacers 285, 290 are formed on the sidewalls of the pillars 215 and the gate electrode material 280, respectively. The spacers 290 expose corner regions of the gate electrodes 280. The spacers 285, 290 may be formed by depositing a conformal layer of spacer material (e.g., SiN, SiBN, SiBCN, SiCN, SiOCN) and anisotropically etching the spacer material to remove the portions formed on horizontal surfaces. Note that the spacer etch also removes a portion of the gate insulation layer 275 formed on a top surface of the hard mask layer 205. In FIG. 20, an interlayer dielectric (ILD) layer 295 (e.g., SiO₂ or a low-k dielectric) is deposited and planarized. For ease of illustration, the ILD layer 295 is not illustrated in the top view in FIG. 20.

FIG. 2P depicts the (SRAM) cell 200 after a patterned etch back of the ILD 295 is performed to define openings 300 for a routing pattern, and the openings 300 are filled with a conductive material (e.g., W, TiN, TaN, WSi₂, TiSi₂, Al) to define routing gates 305, 310, 315, 320, 325. The routing gate 305 couples the gate electrodes 280 of the PG1 and PG2 transistors. The routing gate 310 couples the gate electrodes of the PD2 and PU2 transistors. The routing gate 315 couples the gate electrodes of the PD1 and PU1 transistors. The routing gate 320 couples the gate electrode of the PD2 transistor to a region above a contact pad 330 in the active region 255, and the routing gate 325 couples the gate electrode of the PU1 transistor to a region above a contact pad 335 in the active region 260.

FIG. 2Q depicts the (SRAM) cell 200 after a second ILD layer 340 (e.g., SiO₂, a low-k dielectric, SiON, SiOCN) is deposited and planarized. Contact openings 345 are defined in the ILD layer 340, and contact openings 350 are defined by removing the hard mask layer 205 above the pillars 215. An implantation process 355 is performed to define upper LDD and SD regions 360 in the pillars 215, and an anneal is performed to activate the implanted dopants in the upper and lower SD regions 360, 240.

FIG. 2R depicts the (SRAM) cell 200 after the contact openings 345, 350 are filled with a conductive material (e.g., W, TiN, TiSi, PtSi, Co, Ta) to define external contacts 365 for interfacing with a subsequent wiring structure and internal contacts 370 for connecting the routing gates 320, 325 to the respective contact pads 330, 335. If a base contact communicating with the active regions 255, 260 (i.e., N1 and N2) is desired, additional contacts (not shown) or combinations of a routing gate and a contact (not shown) may be defined in the ILD layer 295 to interface with the silicide layer 265 on the outermost edges of the active regions 255, 260.

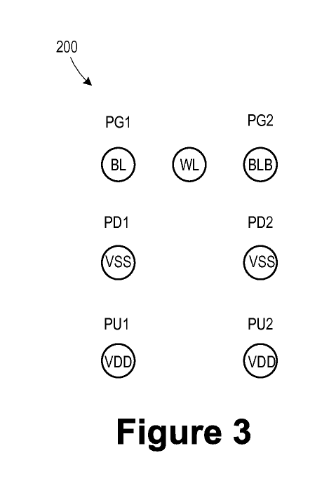

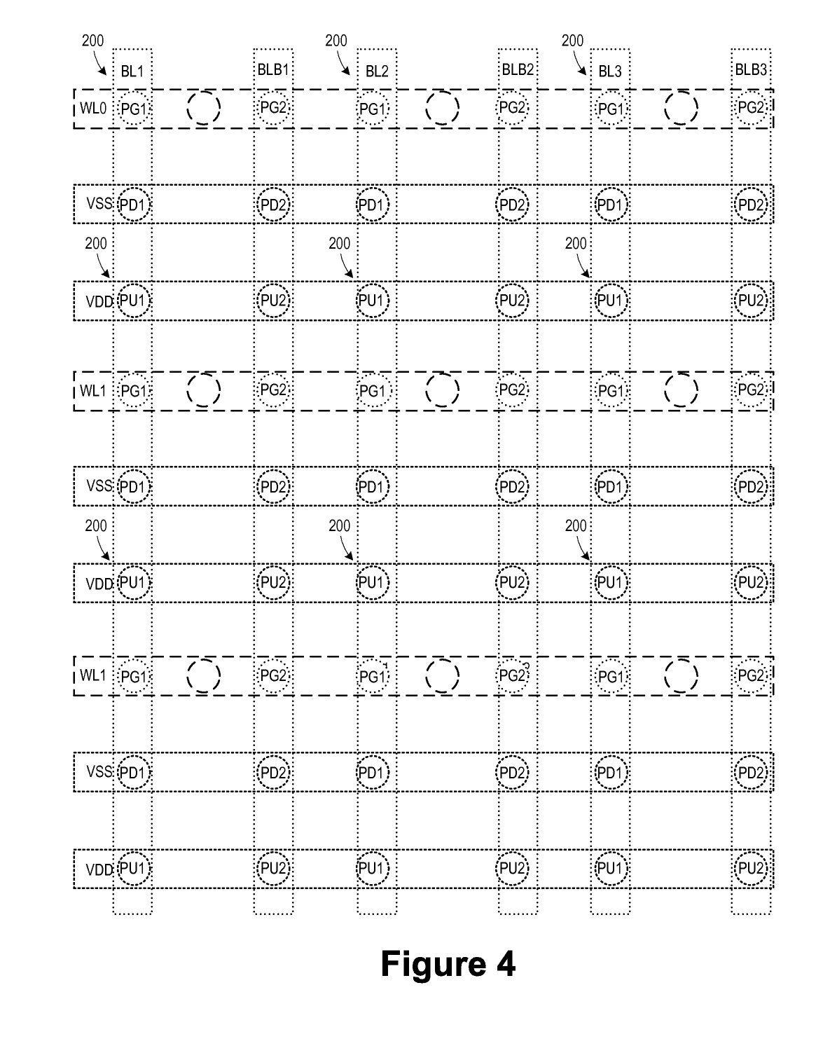

FIG. 3 illustrates the external contacts to the various signal lines for the SRAM cell 200, and FIG. 4 depicts an array of SRAM cells and the exemplary wiring (e.g., W, Cu, Al) for the bit lines BL, BLB, word line WL, positive voltage line VDD, and reference voltage line VSS. The dash pattern of the lines and contacts denote which lines connect to which contacts.

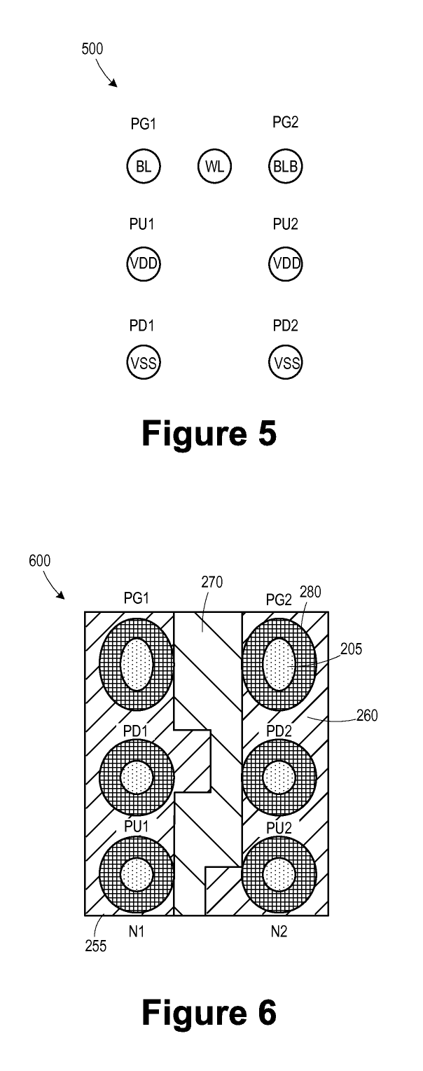

FIG. 5 depicts an SRAM cell 500 with an alternative arrangement of the transistors. The locations of the pull up and pull down transistors are changed. The previously described dopant implantation steps for the well regions, LDD and SD implantations would vary according to the new arrangement.

FIG. 6 depicts an alternative embodiment of an (SRAM) cell 600 where the relative strengths of the transistors may be varied by changing their channel widths. The cross-section of the pillars 215 and the overlying hard mask layers 205 associated with the PG1 and PG2 transistors have a larger area than the cross-section of the other transistors. This arrangement strengthens the PG1 and PG2 transistors relative to the PU1 and PU2 transistors, improving the stability of the (SRAM) cell 600.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming a plurality of pillars of semiconductor material on a substrate;
forming first source/drain regions on a lower portion of each of said pillars;
forming a gate electrode around each of said pillars above said first source/drain region;
forming a second source/drain region on a top portion of each of said pillars above said gate electrode, wherein said first and second source/drain regions and said gate electrode on each of said pillars defines a vertical transistor; and
interconnecting said vertical transistors to define a static random access memory cell.

2. The method of claim 1, wherein interconnecting said vertical transistors further comprises:
forming a first active region in said substrate coupling said first source/drain regions of a first subset of said vertical transistors to define a first node of said static random access memory cell; and
forming a second active region in said substrate coupling said first source/drain regions of a second subset of said vertical transistors to define a second node of said static random access memory cell.

3. The method of claim 2, wherein forming said first active region further comprises forming a first island in said substrate below said first source/drain regions of said first subset of vertical transistors, and forming said second active region further comprises forming a second island in said substrate below said first source/drain regions of said second subset of vertical transistors.

4. The method of claim 3, further comprising forming an insulating material between said first and second islands.

5. The method of claim 3, further comprising forming a silicide layer on at least sidewalls of said first and second islands.

6. The method of claim 2, wherein said first subset comprises a first pass gate transistor, a first pull-down transistor and a first pull-up transistor, said second subset includes a second pass gate transistor, a second pull-down transistor, and a second pull-up transistor, and interconnecting said vertical transistors further comprises:
forming an interlayer dielectric layer above said substrate;
forming a first routing gate in said interlayer dielectric layer to interconnect said gate electrodes of said first and second pass gate transistors;
forming a second routing gate in said interlayer dielectric layer to interconnect said gate electrodes of said first pull-down transistor and said first pull-up transistor;
forming a third routing gate in said interlayer dielectric layer to interconnect said gate electrodes of said second pull-down transistor and said second pull-up transistor;
forming a fourth routing gate in said interlayer dielectric layer connected to said gate electrode of said first pull-up transistor;
forming a fifth routing gate in said interlayer dielectric layer connected to said gate electrode of said second pull-down transistor;
forming a first internal contact in said interlayer dielectric layer connecting said fourth routing gate to said second active region; and
forming a second internal contact in said interlayer dielectric layer connecting said fifth routing gate to said first active region.

7. The method of claim 6, further comprising:
forming a first external contact in said interlayer dielectric material coupled to said first routing gate;
forming a second external contact coupled to said source/drain region of said first pass gate transistor;
forming a third external contact coupled to said source/drain region of said second pass gate transistor;
forming a fourth external contact coupled to said source/drain region of said first pull-down transistor;
forming a fifth external contact coupled to said source/drain region of said second pull-down transistor;
forming a sixth external contact coupled to said source/drain region of said first pull-up transistor; and
forming a seventh external contact coupled to said source/drain region of said second pull-up transistor.

8. The method of claim 6, wherein forming said first and second source/drain regions of said first and second pass gate transistors and said first and second pull-down transistors further comprises implanting a first dopant of a first conductivity type into said first and second source/drain regions of said first and second pass gate transistors and said first and second pull-down transistors and forming said first and second source/drain regions of said first and second pull-up transistors further comprises implanting a second dopant of a second dopant type complementary to said first dopant type into said first and second source/drain regions of said first and second pull-up transistors.

9. The method of claim 8, further comprising:
implanting said first dopant into said first and second source/drain regions of said first and second pass gate transistors and said first and second pull-down transistors and into first portions of said first and second active regions in a first common implantation process; and
implanting said second dopant into said first and second source/drain regions of said first and second pull-up transistors and into second portions of said first and second active regions in a second common implantation process.

10. The method of claim 1, wherein forming said plurality of pillars comprises:
forming a hard mask above said substrate; and
etching said substrate in the presence of said hard mask to define said pillars.

11. The method of claim 10, wherein forming said second source/drain regions further comprises:
forming an interlayer dielectric layer above said substrate;
planarizing said interlayer dielectric layer to expose said hard mask layer;
removing said hard mask layer to define openings exposing the top portions of said pillars; and
implanting dopants into said openings.

12. The method of claim 11, further comprising filling said openings with a conductive material to provide contacts interfacing with said second source/drain regions.

13. A memory cell, comprising:
a plurality of vertical transistors, each comprising:
a pillar of semiconductor material;
a first source/drain region on a lower portion of said pillar;
a gate electrode disposed around said pillar above said first source/drain region;
a second source/drain region on a top portion of said pillar above said gate electrode; and
interconnections between said vertical transistors to define a static random access memory cell.

14. The memory cell of claim 13, wherein said interconnections comprise:
a first active region in said semiconductor material coupling said first source/drain regions of a first subset of said vertical transistors to define a first node of said static random access memory cell; and
a second active region in said semiconductor material coupling said first source/drain regions of a second subset of said vertical transistors to define a second node of said static random access memory cell.

15. The memory cell of claim 14, wherein said first active region comprises a first island of semiconductor material disposed below said first source/drain regions of said first subset of vertical transistors, and said second active region comprises a second island of semiconductor material disposed below said first source/drain regions of said second subset of vertical transistors.

16. The memory cell of claim 15, further comprising an insulating material disposed between said first and second islands.

17. The memory cell of claim 15, further comprising forming a silicide layer on at least sidewalls of said first and second islands.

18. The memory cell of claim 14, further comprising an interlayer dielectric layer above said semiconductor material, wherein said first subset comprises a first pass gate transistor, a first pull-down transistor and a first pull-up transistor, said second subset includes a second pass gate transistor, a second pull-down transistor, and a second pull-up transistor and said interconnections comprise:
a first routing gate in said interlayer dielectric layer interconnecting said gate electrodes of said first and second pass gate transistors;
a second routing gate in said interlayer dielectric layer interconnecting said gate electrodes of said first pull-down transistor and said first pull-up transistor;
a third routing gate in said interlayer dielectric layer interconnecting said gate electrodes of said second pull-down transistor and said second pull-up transistor;
a fourth routing gate in said interlayer dielectric layer connected to said gate electrode of said first pull-up transistor;
a fifth routing gate in said interlayer dielectric layer connected to said gate electrode of said second pull-down transistor;
a first internal contact in said interlayer dielectric layer connecting said fourth routing gate to said second active region; and
a second internal contact in said interlayer dielectric layer connecting said fifth routing gate to said first active region.

19. The memory cell of claim 18, further comprising:
a first external contact in said interlayer dielectric material coupled to said first routing gate;
a second external contact coupled to said source/drain region of said first pass gate transistor;
a third external contact coupled to said source/drain region of said second pass gate transistor;
a fourth external contact coupled to said source/drain region of said first pull-down transistor;
a fifth external contact coupled to said source/drain region of said second pull-down transistor;
a sixth external contact coupled to said source/drain region of said first pull-up transistor; and
a seventh external contact coupled to said source/drain region of said second pull-up transistor.

20. A memory array, comprising:
a plurality of devices arranged in columns and rows, each device comprising:
a plurality of vertical transistors, each comprising:
a pillar of semiconductor material;
a first source/drain region on a lower portion of said pillar;
a gate electrode disposed around said pillar above said first source/drain region;
a second source/drain region on a top portion of said pillar above said gate electrode; and
interconnections between said vertical transistors to define a static random access memory cell including first and second pass gate transistors, first and second pull-down transistors, and first and second pull-up transistors;
a plurality of bit line pairs, each pair coupled to said second source/drain regions of respective first and second pass gates of a column of devices; and
a plurality of word lines, each coupled to said gate electrodes of said first and second pass gates of a row of static random access memory cells.
